(19) United States
(12) Patent Application Publication
(10) Pub. No.: US 2026/0223641 A1
(43) Pub. Date: Jul. 30, 2026

(54) WAFER CHUCK WITH DEFORMABLE CHUCKING SURFACE

(71) Applicant: Maxeon Solar Pte. Ltd., Singapore (SG)

(72) Inventors: RICHARD HAMILTON SEWELL, Los Altos, CA (US); COLIN MARTIN, Soquel, CA (US); MATTHIEU REICH, San Jose, CA (US)

(21) Appl. No.: 19/452,123

(22) Filed: Jan. 16, 2026

Related U.S. Application Data
(60) Provisional application No. 63/751,778, filed on Jan. 30, 2025.

(51) Int. Cl. H10P 72/76

(52) U.S. Cl. CPC H10P 72/7624; H10P 72/7616

(57) ABSTRACT

Embodiments described herein relate to an apparatus that includes a chuck, where the chuck includes a material with a yield strength that is 100MPa or less. In an embodiment, the apparatus may include a channel into a first surface of the chuck, and a hole into a second surface of the chuck. In an embodiment, the hole passes through the chuck and exits within the channel. In an embodiment, the hole has a non-uniform width.

### CROSS-REFERENCE TO RELATED APPLICATIONS

This application claims benefit of U.S. Provisional Patent Application Ser. No. 63/751,778, filed on Jan. 30, 2025, the entire contents of which are hereby incorporated by reference herein.

### BACKGROUND

### 1) Field

Embodiments relate to the field of renewable energy, and in particular, include wafer chucks with deformable chucking surfaces for wire bonding solar cells.

### 2) Description of Related Art

Semiconductor Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Electrical conversion efficiency is an important characteristic of a solar cell as it is directly related to the capability of the solar cell to generate power; with higher efficiency providing additional value to the end customer; and, with all other things equal, higher efficiency also reduces manufacturing cost per Watt. Likewise, simplified manufacturing approaches provide an opportunity to lower manufacturing costs by reducing the cost per unit produced. Accordingly, techniques for increasing the efficiency of solar cells and techniques for simplifying the manufacturing of solar cells are generally desirable.

### BRIEF DESCRIPTION OF THE DRAWINGS

FIGS. 1A-1C illustrate plan views of various stages in a metallization and stringing method for back-contact solar cells, in accordance with an embodiment of the present disclosure.

FIG. 2 illustrates a string of solar cells, in accordance with an embodiment of the present disclosure.

FIG. 3A illustrates a side view of a wire feed and bonding system, in accordance with an embodiment of the present disclosure.

FIG. 3B illustrates a plan view of a wire feed and bonding system that shows the grooves on the feed roller and the compression roller, in accordance with an embodiment of the present disclosure.

FIG. 4A illustrates a perspective view of a chuck for securing solar cell substrates, in accordance with an embodiment of the present disclosure.

FIG. 4B illustrates a perspective view of a chuck for securing cell substrates that is provided over rollers, in accordance with an embodiment of the present disclosure.

FIG. 5A illustrates a cross-sectional view of a chuck and a solar cell substrate that is to be secured against the chuck, in accordance with an embodiment of the present disclosure.

FIG. 5B illustrates a cross-sectional view of a chuck after a solar cell substrate is pressed against the surface of the chuck and the surface of the chuck deforms, in accordance with an embodiment of the present disclosure.

FIG. 6A illustrates a plan view of a bottom surface of a chuck that comprises channels for pulling a vacuum, in accordance with an embodiment of the present disclosure.

FIG. 6B illustrates a plan view of a bottom surface of a chuck that comprises channels for pulling a vacuum with a gasket around the channels, in accordance with an embodiment of the present disclosure.

FIGS. 7A-7C illustrate cross-sectional views of a chuck with vacuum holes that comprise non-uniform diameters, in accordance with embodiments of the present disclosure.

### DETAILED DESCRIPTION

Wire-based metallization and stringing techniques for solar cells, and the resulting solar cells, modules, and equipment used to provide the wire-based metallization on a deformable chuck surface, are described herein. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

The following detailed description is merely illustrative in nature and is not intended to limit the embodiments or the application and uses of such embodiments. As used herein, the word “exemplary” means “serving as an example, instance, or illustration.” Any implementation described herein as exemplary is not necessarily preferred or advantageous over other implementations. Furthermore, there is no intention to be bound by any expressed or implied theory presented in the preceding technical field, background, brief summary or the following detailed description.

References to “one embodiment” or “an embodiment.” do not necessarily refer to the same embodiment. Particular features, structures, or characteristics can be combined in any suitable manner consistent with this disclosure.

Terminology. The following paragraphs provide definitions and/or context for terms found in this disclosure (including the appended claims):
“Comprising” is open-ended term does not foreclose additional structure or steps.

“Configured to” connotes structure by indicating that a device, such as a unit or a component, includes structure that performs a task or tasks during operation, such structure is configured to perform the task even when the device is not currently operational (e.g., is not on/active). A device “configured to” perform one or more tasks is expressly intended to not invoke a means or step plus function interpretations under 35 U.S.C. § 112, (f) or sixth paragraph.
“First,” “second,” etc. terms are used as labels for nouns that they precede, and do not imply any type of ordering (e.g., spatial, temporal, logical, etc.). For example, reference to a “first” solar cell does not necessarily mean such solar cell in a sequence; instead the term “first” is used to differentiate this solar cell from another solar cell (e.g., a “second” solar cell).
“Coupled” refers to elements, features, structures or nodes unless expressly stated otherwise, that are or can be directly or indirectly joined or in communication with another element/node/feature, and not necessarily directly mechanically joined together.
“Inhibit” describes reducing, lessening, minimizing or effectively or actually eliminating something, such as completely preventing a result, outcome or future state completely.
“Doped regions,” “semiconductor regions,” and similar terms describe regions of a semiconductor disposed in, on, above or over a substrate. Such regions can have a N-type conductivity or a P-type conductivity, and doping concentrations can vary. Such regions can refer to a plurality of regions, such as first doped regions, second doped regions, first semiconductor regions, second semiconductor regions, etc. The regions can be formed of a polycrystalline silicon on a substrate or as portions of the substrate itself.
“Thin dielectric layer,” “tunneling dielectric layer,” “dielectric layer,” “thin dielectric material” or intervening layer/material refers to a material on a semiconductor region, between a substrate and another semiconductor layer, or between doped or semiconductor regions on or in a substrate. In an embodiment, the thin dielectric layer can be a tunneling oxide or nitride layer of a thickness of approximately 2 nanometers or less. The thin dielectric layer can be referred to as a very thin dielectric layer, through which electrical conduction can be achieved. The conduction can be due to quantum tunneling and/or the presence of small regions of direct physical connection through thin spots in the dielectric layer. Exemplary materials include silicon oxide, silicon dioxide, silicon nitride, and other dielectric materials.
“Intervening layer” or “insulating layer” describes a layer that provides for electrical insulation, passivation, and inhibit light reflectivity. An intervening layer can be several layers, for example a stack of intervening layers. In some contexts, the insulating layer can be interchanged with a tunneling dielectric layer, while in others the insulating layer is a masking layer or an “antireflective coating layer” (ARC layer). Exemplary materials include silicon nitride, silicon oxynitride, silicon dioxide, aluminum oxide, amorphous silicon, polycrystalline silicon, molybdenum oxide, tungsten oxide, indium tin oxide, tin oxide, vanadium oxide, titanium oxide, silicon carbide and other materials. In an example, the intervening layer can include a material that can act as a moisture barrier. Also, for example, the insulating material can be a passivation layer for a solar cell.
“Substrate” can refer to, but is not limited to, semiconductor substrates, such as silicon, and specifically such as single crystalline silicon substrates, multi-crystalline silicon substrates, wafers, silicon wafers and other semiconductor substrates used for solar cells. In an example, such substrates can be used in micro-electronic devices, photovoltaic cells or solar cells, diodes, photo-diodes, printed circuit boards, and other devices. These terms are used interchangeably herein.
“About” or “approximately”. As used herein, the terms “about” or “approximately” in reference to a recited numeric value, including for example, whole numbers, fractions, and/or percentages, generally indicates that the recited numeric value encompasses a range of numerical values (e.g., +/−5 % to +/−10% of the recited value) that one of ordinary skill in the art would consider equivalent to the recited value (e.g., performing substantially the same function, acting in substantially the same way, and/or having substantially the same result).

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Disclosed herein are solar cells. In one embodiment, a substrate may include a back surface and an opposing light-receiving surface. A plurality of semiconductor regions is disposed in or above the back surface of the substrate. A conductive contact structure is disposed on the semiconductor regions. The conductive contact structure includes a plurality of conductive wires, each conductive wire of the plurality of conductive wires essentially continuously bonded directly to a corresponding one of semiconductor regions. In an additional embodiment, each conductive wire of the plurality of conductive wires can be bonded through a metal layer to one of the semiconductor regions. In an example, the metal layer can be a metal seed layer. In an embodiment, each conductive wire of the plurality of conductive wires can be a non-coated conductive wire. In one example, the conductive contact structure can include a non-coated conductive wire or a plurality of non-coated conductive wires.

Also, disclosed herein are strings of solar cells. In one embodiment, a string of solar cells includes a plurality of solar cells, such as back-contact solar cells or front contact solar cells. Each of the plurality of back-contact solar cells includes P-type and N-type doped diffusion regions. A plurality of conductive wires is disposed over a back surface of each of the plurality of solar cells, wherein each of the plurality of wires is substantially parallel to the P-type and N-type doped diffusion regions of each of the plurality of solar cells. Every other one of the plurality of wires is cut in a region between each adjacent pair of the plurality of solar cells.

Also disclosed herein are methods of fabricating strings of solar cells. In one embodiment a method of electrically coupling solar cells involves aligning conductive wires over the back sides of adjacent solar cells. The wires are aligned substantially parallel to P-type and N-type doped diffusion regions of the solar cells. The method involves bonding the wires directly to the back side of each of the solar cells over the P-type and N-type doped diffusion regions using thermocompression bonding, ultrasonic bonding, or thermosonic bonding.

Also disclosed herein are wire bonding systems for electrically coupling solar cells. In one embodiment, a wire bonding system includes one or more of a creel assembly containing a plurality of wire spools, a coarse pitch assembly with a plurality of coarse pitch combs, a fine pitch comb, a feed roller, and a compression roller. Various capstans, rollers, and/or the like may be provided within the wire bonding system to control tension of wires that are fed through the wire bonding system. In an embodiment, one or both of the feed roller or the compression roller may comprise grooves that are configured to align conductive wires substantially parallel with P-type and N-type doped diffusion regions of each of the solar cells in order to bond the wires to the back side of each of the solar cells over the P-type and N-type doped diffusion regions.

Embodiments disclosed herein include the materials and architectures that are used to provide improved chucking surfaces for such wire bonding processes. In some instances, the surfaces of the solar cells that receive sunlight are textured and/or patterned to improve efficiency of the solar cell. For example, the textured surface may comprise light trapping pyramids that may be several microns high. During the wire bonding process, the compression roller is pressed against the backside of the solar cell with significant force (e.g., in the order of thousands of Newtons). The small surface area provided by the textured surface may result in high pressures being applied to the textured features. When the chuck is a rigid material, this may result in damage to the textured features. In the case of light trapping pyramids, the pyramids may crack and/or fracture, which leads to a significant reduction in the efficiency of the solar cell.

Accordingly, embodiments described herein may include a material for the chuck that is deformable under the pressure applied by the compression roller. A suitable deformable material should also comprise a high thermal conductivity in order to spread heat evenly throughout the surface of the chuck. The chuck material may also include a material that is machinable and able to remain flat at high temperatures. One suitable material for the chuck comprises graphite. In some embodiments, suitable materials that may be useful for the chuck may include soft materials. For example, materials with a yield strength up to approximately 100 MPa or up to approximately 50 MPa may be used for the chuck in some embodiments. In one embodiment, graphite may be used for the chuck.

Graphite may have a yield strength that allows for the textured surface of the solar cell to deform a surface of the graphite chuck during thermocompression bonding. In an embodiment, the textured surface may at least partially embed within the chuck during bonding. As such, the forces are not concentrated at the tips of the pyramids, and are instead distributed across the surfaces of the pyramids.

It is to be appreciated that the use of relatively soft materials for the chuck runs contrary to traditional designs for chucks in the solar and/or semiconductor industries. Typically, chucks are designed with hard materials that have high yield strengths in order to prevent damage to the chuck during use. This allows for the chuck to have a longer useable life and limits downtime to replace damaged and/or worn chucks. However, typical semiconductor and/or solar processing do not operate with such high forces being applied against the substrate and the chuck. As such, typical semiconductor and/or solar processing do not result in damage to the textured surface that is seen with thermocompression wire bonding of solar cells described herein. Accordingly, alternative material selections for the chucks described herein are used to solve problems that are not present in typical semiconductor and/or solar processing environments.

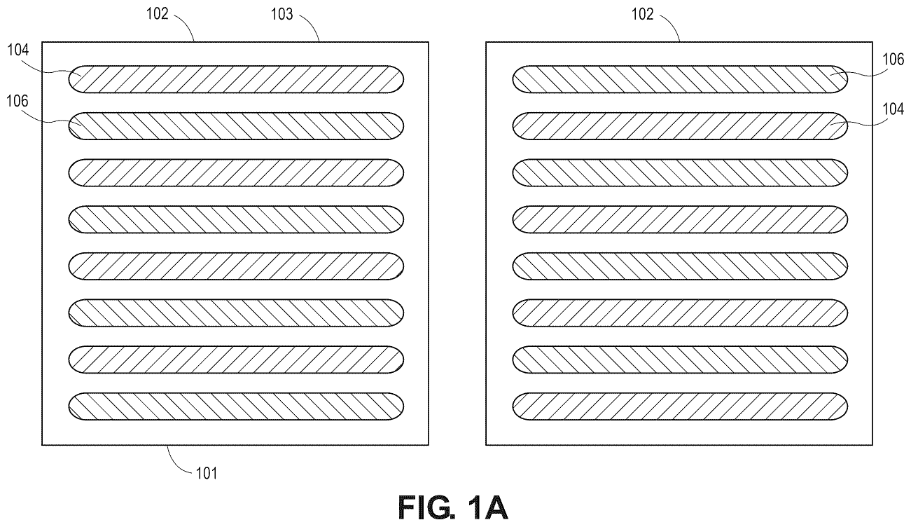

FIGS. 1A-1C illustrate plan views of various stages in a metallization and stringing method for back-contact solar cells, in accordance with an embodiment of the present disclosure.

FIG. 1A illustrates a back-side view of adjacent solar cells 102 that are to be stringed together, including alternating P-type doped diffusion regions 104 and N-type doped diffusion regions 106. In one such embodiment, each of the plurality of solar cells 102 is substantially rectangular, and the P-type doped diffusion regions 104 and the N-type doped diffusion regions 106 are substantially parallel to the edges 101, 103 of the solar cells 102. A solar cell that is substantially rectangular could be, for example, a square, or another rectangular shape, and can have standard, cut, or rounded corners. As illustrated in FIG. 1A, the solar cells 102 are asymmetric in the sense that the solar cells 102 end with a P finger on one side (e.g., side 103) and an N finger on the opposite side (e.g., side 101). The asymmetric solar cells can then be placed in alternating orientations along the string, as illustrated in FIG. 1A. The asymmetric solar cell design together with the alternating orientations along the string enable the use of wires that are parallel to the edges 101, 103 of the solar cells because the P finger on one of the solar cells is directly across from the N finger of the adjacent solar cell, as is explained below with respect to FIG. 1C.

Referring to FIG. 1B, a method of metallization and stringing includes attaching a non-conductive shield, tape or paint strip 108 to the back sides of the adjacent solar cells 102. The non-conductive shield, tape or paint strip 108 can serve to hide the wires when viewed from the front. In some embodiments, non-conductive shield, tape or paint strip 108 is applied to the adjacent solar cells 102 before the conductive wires 110 are applied. In other embodiments, the conductive wires are bonded to the adjacent solar cells 102 so that the conductive wires 110 are not bonded up to edges of the solar cells 102. In such an embodiment, the non-conductive shield, tape or paint strip 108 is then inserted between the back of the solar cells 102 and the conductive wires 110. In yet another embodiment, the non-conductive shield, tape or paint strip 108 may be placed on the sunny side (i.e., the top side of the adjacent solar cells 102). Thus, the non-conductive shield covers exposed sections of the wires between each adjacent pair of the plurality of solar cells. Therefore, according to embodiments, the non-conductive shield, tape or paint strip 108 includes a material that is substantially opaque to sufficiently cloak the wires when viewed from the front. The non-conductive shield, tape or paint strip 108 can also assist in alignment of the solar cells, and/or holding the solar cells 102 together. The non-conductive shield, tape or paint strip 108 can include materials such as polypropylene or polyethylene, and can further include an adhesive layer like an acrylate. A non-conductive shield, tape or paint strip 108 with an adhesive layer can be beneficial to assist in alignment. Although a non-conductive shield, tape or paint strip 108 can be beneficial for the reasons explained above, other embodiments do not include a non-conductive shield (e.g., the non-conductive shield 108 can be optional).

Referring to FIG. 1C, the method of metallization and stringing includes aligning conductive wires 110 over the back sides of adjacent solar cells 102. As shown in FIG. 1C, the non-conductive shield, tape or paint strip 108 is present during the conductive wire 110 bonding. In other embodiments, the non-conductive shield, tape or paint strip 108 may be applied after the conductive wires 110 are bonded to the solar cells 102. In one embodiment, the wires 110 are aligned substantially parallel to the P-type doped diffusion regions 104 and N-type doped diffusion regions 106 of the solar cells 102. The wires 110 can have a cross-sectional shape that is round, flattened, slightly flattened, or another shape. Round wires can be beneficial because they can be rolled or twisted. In an embodiment involving the alignment and placement of round wires, the wires can be flattened prior to or during bonding the wires to the back side of each of the solar cells.

Conductive wires include an electrically conducting material (e.g., a metal such as aluminum, copper or another suitable conductive material), with or without a coating such as tin, silver, or nickel. In an embodiment, an organic solderability protectant is not used on the wires. In another embodiment, an organic solderability protectant is used on the wires. In the embodiment illustrated in FIG. 1C, the number of wires is equal to (or substantially equal to) the number of diffusion regions of each of the plurality of solar cells. In one example, the number of wires can be approximately between 5 -15 wires, between 10-20 wires, between 15-25 wires, between 20-30 wires, between 25-35 wires, between 30-40 wires, between 35-45 wires, between 10-50 wires, or greater than 50 wires. In one such embodiment, a single wire is aligned over each of the P-type doped diffusion regions 104 and N-type doped diffusion regions 106 of the solar cells 102. According to one embodiment, each of the wires 110 is roughly centered over one of the P-type doped diffusion regions 104 and N-type doped diffusion regions 106 of the solar cells 102. As illustrated in FIG. 1C, the wires 110 can be aligned so that they are substantially parallel to the edges 101, 103 of the plurality of solar cells 102.

Referring again to FIG. 1C, the wires 110 can be aligned via a variety of mechanisms. For example, in one embodiment, aligning the conductive wires 110 over the back sides of adjacent solar cells 102 involves use of a grooved roller or a bond head. Other mechanisms can be used to align the conductive wires 110 over the P-type doped diffusion regions 104 and N-type doped diffusion regions 106 of the solar cells 102 instead of, or in addition to, a grooved roller or a bond head. For example, according to one embodiment, a reed, or other mechanism suitable for aligning and guiding the conductive wires can be used. When aligning wires over a solar cell that is not the first solar cell, the presence of wires bonded to the first solar cell can assist in alignment of the wires over the subsequent solar cells, in accordance with an embodiment.

After aligning the conductive wires 110, the conductive wires are bonded to the back side of the solar cells 102 the P-type doped diffusion regions 104 and N-type doped diffusion regions 106 of the solar cells 102, e.g., using thermocompression bonding or ultrasonic bonding approaches as described herein. Referring again to FIG. 1C, according to one embodiment, the method of metallization and stringing includes cutting every other one of the wires 110 between each adjacent pair of the solar cells 102. As illustrated in FIG. 1C, the wires 110 are cut at the locations 112, such that all of the wires connected to the P-type diffusion on one side of a solar cell 102, and all of the wires connected to the N-type diffusion of the opposite side of the solar cell are cut.

Prior to cutting the wires 110 in the locations 112, the pair of solar cells are shorted. Cutting the wires 110 enables electrically coupling the solar cells for collection of current from the solar cell string. Cutting the wires 110 in the locations 112 can involve any wire cutting technique. For example the wires 110 can be cut in the locations 112 with a laser or a blade. Although the FIGS. 1A-1C illustrate only two solar cells, a solar cell string can include any number of solar cells stringed together (e.g., 2 or more solar cells stringed together). The process is continuous in the sense that arbitrarily long strings of solar cells can be made.

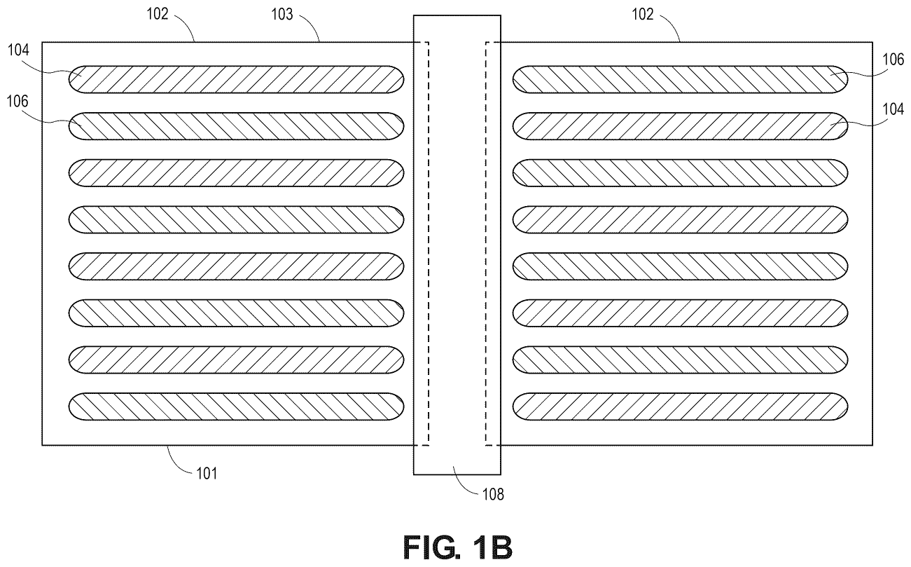

FIG. 2 illustrates one example of a string of solar cells, in accordance with an embodiment of the present disclosure. The solar cell string 200A illustrated in FIG. 2 includes a plurality of solar cells 202 that are electrically coupled together in series. The solar cell string 200A has two end solar cells 201, and inner solar cells 203 connected in series between the two end solar cells 201. Each of the two end solar cells 201 is electrically coupled with a busbar 214. At each of the end solar cells 201, every other one of the wires is coupled with a busbar 214 to couple only one of the two electrodes of the end solar cell, either the P-type doped diffusion regions 204 or the N-type doped diffusion regions 206. In one embodiment, the coupling of every other one of the wires from an end solar cell 201 with a busbar 214 can be achieved by first cutting all the wire at each end of the string, and connecting only the wires for either the P-type or N-type doped diffusion regions. Alternatively, all the wires for an end solar cell 201 can first be connected to a busbar 214, and then every other wire can be cut in the locations 212.

Only the end solar cells 201 are connected to a busbar 214, in contrast to other stringing techniques which can involve attaching busbar(s) to each solar cell, according to some embodiments. Though, embodiments may also include busbars 214 between each solar cell 201 as well. The busbars 214 can couple the solar string 200A with another solar string (e.g., such as the solar string 200B), or to another circuit (e.g., a circuit outside the module through a junction box).

As illustrated in FIG. 2, in one embodiment, a given cut section of wire is to electrically couple at most two solar cells together in series, wherein the P-type doped diffusion area of one of the two solar cells is connected to the N-type doped diffusion area of the other solar cell. However, other embodiments can include more than two solar cells being coupled together with a given cut section of wire. For example, if solar cells are connected in parallel, it is possible to connect more than two cells with a given cut section of wire. Also as illustrated in FIG. 2, in one embodiment, a cut section of wire that electrically couples an end solar cell 201 to the busbar 214 couples a single solar cell to the busbar 214. However, as mentioned above, in embodiments that connect solar cells in parallel, a given cut section of wire can connect more than a single solar cell to the busbar. Thus, a solar string can be created using the plurality of wires 210 by aligning and bonding the wires over the P-type and N-type doped diffusion regions of each of the solar cells, followed by cutting some of the wires to achieve the desired configuration of solar cells in a string.

Thus, in accordance with one or more embodiments of the present disclosure, a stringing method provides a structure having compressed wires against one or more solar cells. In an embodiment, every second wire is cut between wafers and busbars at ends.

As can be appreciated, aligning and bonding the number of wires to the proper diffusion regions in a high volume assembly environment is a complex task. Accordingly, embodiments disclosed herein include a wire feed and bonding system. The wire feed and bonding system allows for a plurality of electrically conductive wires to be fed from a plurality of spools to specified grooves on a compression roller. The grooves on the compression roller are configured to be aligned with different diffusion regions on a solar cell. A plurality of solar cells that are secured to one or more chucks may pass below the compression roller (e.g., on a conveyor and/or track based system), and the wires are bonded to each solar cell as the solar cells pass below the compression roller. In some embodiments, the wires are bonded to diffusion regions of each solar cell, to poly-silicon regions of each solar cell, or any other desired location along the solar cell.

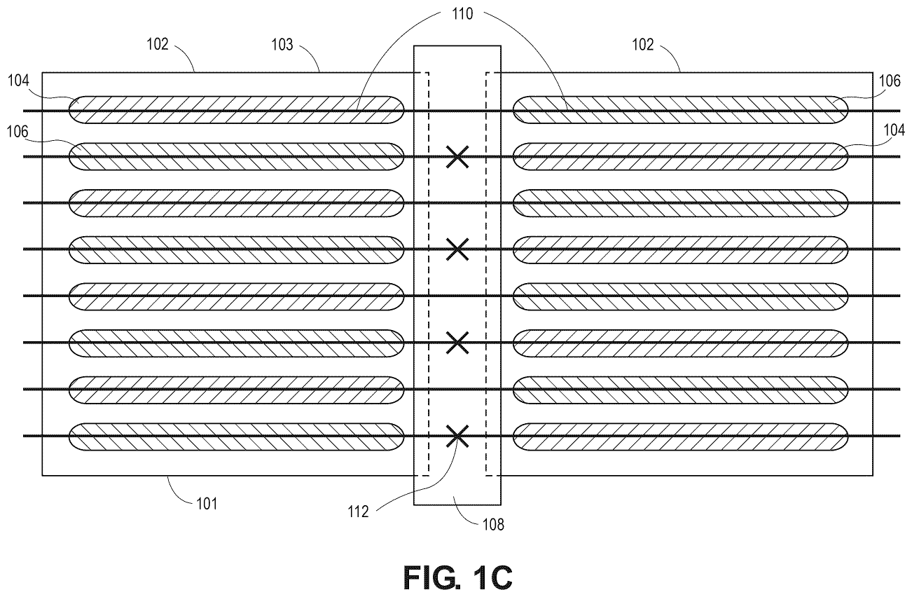

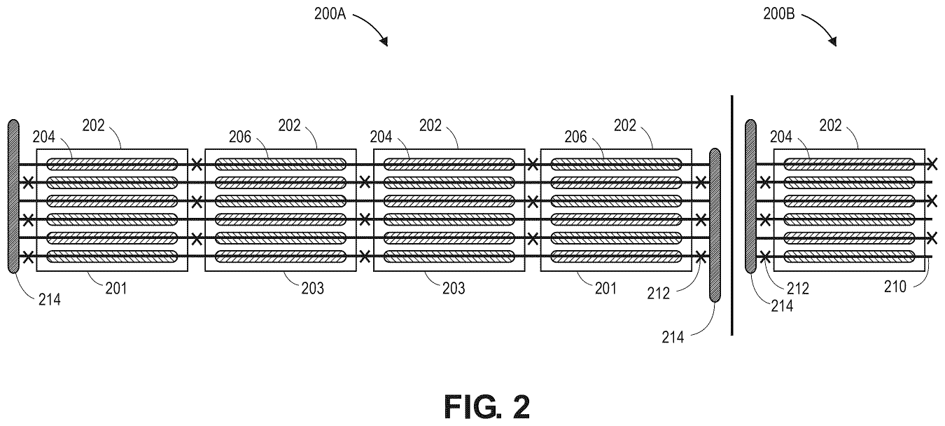

Referring now to FIG. 3A, a cross-sectional illustration of a wire feed system 320 that guides a plurality of electrically conductive wires 315 to a feed roller 341 and a compression roller 342 is shown, in accordance with an embodiment. The wires 315 may comprise any electrically conductive material that is suitable for being wire bonded to solar cells. One or more embodiments described herein may include an aluminum wire. It is to be appreciated that, in some embodiments, aluminum wires 315 are preferred since they can be subjected to thermocompression bonding at a temperature in a range of approximately 300-450 degrees Celsius, or lower with the inclusion of ultrasonic energy. In a particular example, the bonding temperature can include approximately 350 degrees Celsius. By contrast, a copper wire may need to be heated to substantially higher temperatures for thermocompression bonding and, as a result, can cause a silicon substrate to bow upon cooling after bonding to the silicon substrate. It is also to be appreciated that excessive bowing with copper wires can result from the fact that copper has a higher yield strength than pure aluminum.

On cooling, both aluminum and copper will contract to drive wafer bowing, but the degree of contraction in aluminum is limited by the low yield strength. Many aluminum alloys have higher yield strength (e.g., 241 MPA for AL 6061) while pure aluminum has a yield strength of 11 MPA. Accordingly, in some embodiments, pure or essentially pure aluminum wires are used for forming a metallization layer for silicon based solar cells to enable low bowing. Additionally, the lower yield strength allows for lower forces to plastically deform the wire, which is beneficial for thermocompression bonding. In an example, the aluminum wires do not include any additional coating or layer. Copper may also form thick oxides in air at the high temperatures required for thermocompression bonding, whereas an oxide of aluminum is self-limiting. However, in other embodiments, copper wires or any other wire material described herein (with or without a coating) may be used for forming a metallization layer for solar cells with the wire feed and bonding system 300.

In an embodiment, the spools (not shown) may feed wires 315 to a coarse pitch assembly that comprises a plurality of coarse pitch combs 322. In the illustrated embodiment, four coarse pitch combs 322_{A}-322_{D} are oriented in a vertical stack. Though, the coarse pitch combs 322 may be provided with any spatial positioning.

In an embodiment, each of the coarse pitch combs 322 may comprise a plurality of channels or slots (out of the plane of FIG. 3A). In an embodiment, a pitch of the channels may be an integer multiple of the desired final pitch. In a particular embodiment, the integer multiple is equal to the number of coarse pitch combs 322 provided in the wire feed system 320. For example, in FIG. 3A the pitch of the channels 325 may be approximately four times the desired final pitch of the wires 315. In a particular embodiment, the pitch of the channels 325 may be between approximately 1 mm and approximately 5.0 mm. For example, the pitch of the channels may be approximately 2.0 mm. Though, it is to be appreciated that smaller or larger pitches may also be used for the channels in other embodiments.

In an embodiment, the wires 315 may be routed from the coarse pitch combs 322 to a single fine pitch comb 330. The fine pitch comb 330 may align the wires 315 into a single horizontal plane. The fine pitch comb 330 may have a plurality of channels (out of the plane of FIG. 3A) that are spaced at a fine pitch that is smaller than the coarse pitch. In an embodiment, the fine pitch is substantially equal to the pitch of grooves (not shown) on the compression roller 342. For example, the fine pitch may be between 0.1 mm and 1.0 mm. In the case of a coarse pitch of approximately 2.0 mm with four coarse pitch combs 322, the fine pitch may be approximately 0.5 mm.

In an embodiment, the wires 315 may at least partially wrap around one or more rollers between the coarse pitch combs 322 and the fine pitch comb 330. For example, each wire 315 may pass through a driven capstan roller 326 and an idle roller 327. The driven capstan roller 326 may be driven by a motor or the like. The idle roller 327 may spin passively as wire 315 is drawn through the system. The driven capstan roller 326 allows for the tension in the wire 315 to be decreased before reaching the fine pitch comb 330. That is, the tension in the wires 315 between spools in a creel assembly and the coarse pitch combs 322 may be higher than a tension in the wires 315 between the coarse pitch combs 322 and the fine pitch comb 330. While a roller assembly with two rollers (e.g., driven capstan roller 326 and idle roller 327) is shown, embodiments may include one or more rollers, or rollers may be omitted from the system 300.

In an embodiment, the wires 315 may be routed from the coarse pitch combs 322 to the fine pitch comb 330 through the use of transfer caps (not shown in FIG. 3A). Each transfer cap may have slots that receive the ends of each wire 315 of a given coarse pitch comb 322, and the transfer cap delivers the wires 315 to the fine pitch comb 330. Each of the transfer caps may be offset from each other by one fine pitch. This allows for the wires 315 from all of the coarse pitch combs 322 to be interleaved with each other at the fine pitch comb 330 in an orderly manner.

As shown, the wires 315 that exit the fine pitch comb 330 may partially wrap around the feed roller 341 and partially wrap around the compression roller 342. The compression roller 342 may compress the wires 315 against substrates 351, such as wafers comprising solar cells. For example, the substrates 351 may comprise solar cells similar to any of the solar cells described in greater detail herein. As a chuck 350 is displaced relative to the compression roller 342, the wires 315 are bonded across the substrates 351 to provide an electrically connected string of solar cells, similar to any of the string of solar cells described in greater detail herein. A more detailed description of the chuck 350 is provided in greater detail herein. In an embodiment, the compression roller 342 may be pressed against the substrates with a force sufficient to provide thermocompression bonding between the wires 315 and the substrates 451 at a desired temperature.

Referring now to FIG. 3B, a plan view illustration of a portion of a wire feed and bonding system 300 is shown, in accordance with an embodiment. In an embodiment, the entire length of wires 315_{A} from the coarse pitch comb 322 to the compression roller 342 is shown. The remaining wires 315_{B}-315_{D} extend from the compression roller 342 to the fine pitch comb 330. Thereafter, wires 315_{B}-315_{D} extend out of the plane of FIG. 3B to coarse pitch combs 322 above or below the illustrated coarse pitch comb 322.

In an embodiment, the coarse pitch comb 322 may be similar to any of the coarse pitched combs described in greater detail herein. For example, the coarse pitch comb 322 may comprise a plurality of round pins 328 that define coarse pitch channels 325. The wires 315_{A} may then wrap through a driven capstan roller 326 and an idle roller 327 before being inserted into the slots 332 of the fine pitch comb 330. As shown, the wires 315_{A} are placed at every fourth slot 332. In an embodiment, the fine pitch comb 330 may be similar to any of the fine pitch combs described in greater detail herein.

In an embodiment, the wires 315_{A}-315_{D} may pass from the fine pitch comb 330 into grooves 344 that are formed on a surface of the feed roller 341. The grooves 344 may have a depth that is greater than the diameter of the wires 315. The wires 315 are then fed into the grooves 348 of the compression roller 342. The grooves 348 and the grooves 344 may have substantially the same pitch when the system 300 is operating and/or the feed roller 341 and the compression roller 342 are at a desired operating temperature.

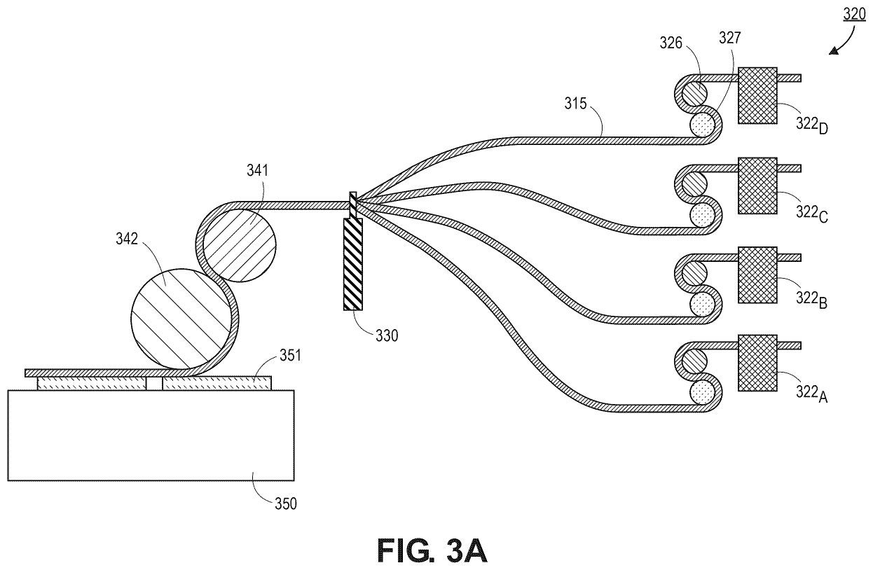

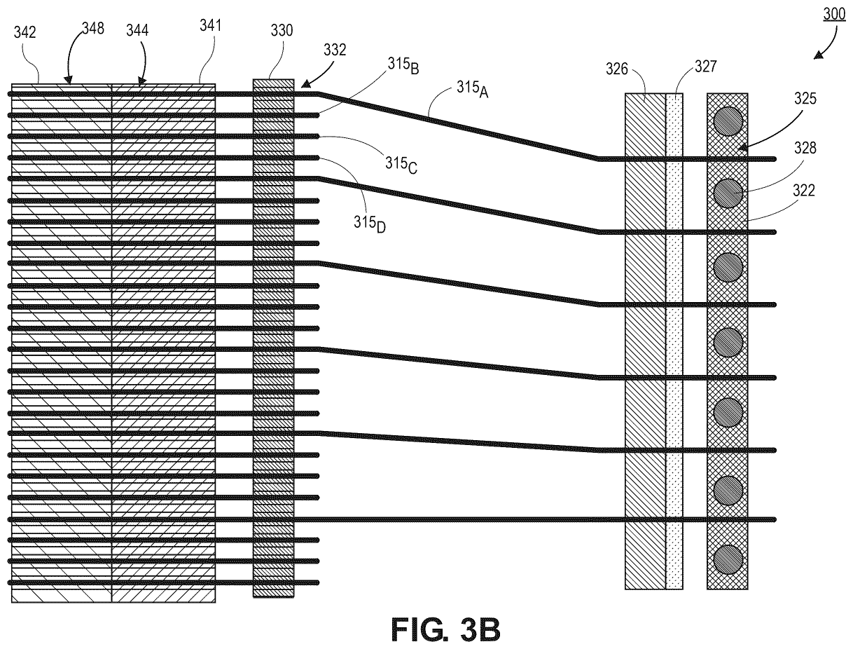

As noted above, embodiments disclosed herein include materials and architectures for the chuck 350 that are chosen to benefit the efficiency of solar cells that are wired with thermocompression bonding. For example, the material for the chuck 350 may be a soft thermally conductive material, such as graphite. FIGS. 4A and 4B provide a more detailed description of chuck assemblies 460 in accordance with embodiments disclosed herein.

Referring now to FIG. 4A, a perspective view illustration of a chuck assembly 460 is shown, in accordance with an embodiment. In an embodiment, the chuck assembly 460 comprises a chuck 450. The chuck 450 may comprise a material that enables thermocompression bonding to the backside of substrates 451 (e.g., solar cells) that are secured to the chuck 450. The chuck 450 may secure the substrates 451 with a vacuum or sub-atmospheric pressure that is generated through holes (not shown) that pass through the chuck 450. For example, one or more vacuum lines 457 may be fluidically coupled between a vacuum pump (not shown) and one or more vacuum channels and holes of the chuck 450. In an embodiment, the vacuum lines 457 are coupled to a hotplate 455 below the chuck 450.

In the illustrated embodiment, a pair of substrates 451 are secured to a single chuck 450. Other embodiments may include a chuck 450 that is configured to secure one or more substrates 451. In an embodiment, the substrates 451 may comprise semiconductor substrates (e.g., silicon substrates) on which solar cells are fabricated. The substrates 451 may have any suitable form factor. The substrates 451 in FIG. 4A are shown as being substantially rectangular with faceted or rounded corners. Though, substrates 451 with other form factors and/or shapes may also be used.

In some embodiments, the chuck 450 may also be configured to secure one or more busbars 452. In FIG. 4A, a pair of busbars 452 are provided on the outer edges of the chuck 450. Other embodiments may comprise a chuck 450 configured to secure a busbar 452 between substrates 451.

The chuck 450 may also comprise a recess 453 into which the substrates 451 sit. The inclusion of recess 453 may be beneficial since bonding wire to the substrate 451 may result in the potential to over compress the wires within approximately 2.0 mm of the edge of the substrate 451 when the top surface of the substrates 451 are raised up above the top surface of the chuck 450. This is because the entire force of the compression roller may become concentrated on a smaller total area of the substrate 451. Accordingly, the recess 453 (or pocket) may be formed into the surface of the chuck 450, so that the top surface of the substrate 451 is substantially coplanar with the surface of the chuck 450. As the compression roller rolls off the end of the substrate 451, the chuck 450 is able to support the wire and roller to reduce the variation in pressure on the wire at the edge of the substrate 451. In an embodiment, a depth of the recess 453 may be substantially equal to a thickness of the substrate 451.

As noted above, the chuck 450 may comprise a material that is stable at high temperature and does not damage the front surface of the substrate 451 during the thermocompression bonding. Soft materials (e.g., with a yield strength of up to approximately 100 MPa or up to approximately 50 MPa) may satisfy such design choices. It is believed that the textured surface (e.g., pyramids) of the front surface of the substrate 451 are able to partially embed into the soft material so that the forces are not concentrated at the tips of one or more of the front surface pyramids. Instead, the forces are able to be distributed across a larger area of the surfaces of the pyramids.

In one embodiment, graphite is a suitable material for this purpose since graphite is stable at high temperatures, has good thermal conductivity, is easily machined into complex shapes, and enables high forces to be applied to the backside of the substrate 451 without damaging the frontside of the substrate 451 that is in contact with the graphite. Different types of graphite may be used for the chuck 450. In one embodiment, the graphite may comprise an isostatically molded fine grain graphite. Such graphite may exhibit high thermal conductivity to prevent temperature gradients in the chuck which may lead to undesirable bowing or warping due to thermal expansion mismatch.

In an embodiment, the high thermal conductivity of graphite enables the use of simple heating methods such as cartridge heaters or bendable heater elements without needing complex designs for thermal uniformity. For example, heaters 456 may be embedded in the hotplate 455 that is directly below the chuck 450. In some embodiments, the hotplate 455 may comprise the same material as the chuck 450, or the hotplate 455 and the chuck 450 may comprise different materials.

The hotplate 455 and the chuck 450 may be discrete components. This allows for easier manufacturing and maintenance of the chuck assembly. For example, grooves (not shown) for routing the vacuum lines to holes that pass through a thickness of the chuck 450 below the substrates 451 can be formed into the backside of the chuck 450. Soft materials, such as graphite may also be flat and smooth enough at high temperature to form a sufficient vacuum seal against the hotplate 455. Accordingly, some embodiments may allow for a vacuum chuck 450 that omits a high temperature gasket below the chuck 450. Though, as will be described in greater detail herein, a gasket may be used in some embodiments. Additionally, the use of separate components allows for the chuck 450 to be easily replaced for maintenance. The removed chuck 450 may be resurfaced to extend a useable lifespan of the chuck 450 as well.

In an embodiment, the chuck 450 may be supported by a rigid mechanical system that allows for large forces to be applied to the wafer surface with minimal deflection or plastic deformation of the structure as well as limiting heat loss from the chuck 450. In one embodiment, structural support and thermal isolation of the chuck 450 may be provided by a support plate 458 that is provided below the hotplate 455. In an embodiment, the support plate 458 may comprise a material that is a good thermal insulator while also having good compressive strength. For example, ceramics, composites, and/or the like may be used for the support plate 458. The support plate may comprise materials such as silica, aluminosilicates, alumina, silicon carbide, zirconia, magnesia, and/or the like.

While shown as a rectangular prism in FIG. 4A, some embodiments may comprise a support plate 458 that is shaped in such a way to correct for any non-uniformities in wire compression across the width of the substrate 451. Alternative embodiments may also comprise the inclusion of a thin metal shim that is placed between the support plate 458 and the chuck 450 to correct for such wire compression non-uniformities.

In an embodiment, the chuck assembly 460 may further comprise a carrier 464 that is mounted to linear guides 465. The carrier 464 and linear guides 465 may be coupled to a the thermocompression bonding tool in order to transport the chuck 450 across the compression roller. Chuck lateral supports 468 that secure the chuck 450 in the X-Y plane may be coupled to the carrier 464 by end supports 467. In some embodiments, a fan assembly 463 may blow air through a cooling tunnel 462 that is below the support plate 458. In an embodiment, a metal support plate 459 may be provided between the insulating support plate 458 and the cooling tunnel 462.

Referring now to FIG. 4B, a perspective view illustration of an alternative chuck assembly 460 is shown, in accordance with an embodiment. In an embodiment, the chuck assembly 460 in FIG. 4B may be similar to the chuck assembly 460 in FIG. 4A, with the exception of the thermal isolation solution. For example, FIG. 4B may comprise a high strength metal plate 461 (e.g., stainless steel) underneath the chuck 450 and the hotplate 455. In order to minimize thermal losses from the chuck 450, the metal plate 461 may have a small contact area with the lower portion of the chuck assembly 460. For example, a reduced contact area may be provided by tangential contact with a roller 454 that provides support to the metal plate 461 as the chuck 450 travels underneath a compression roller.

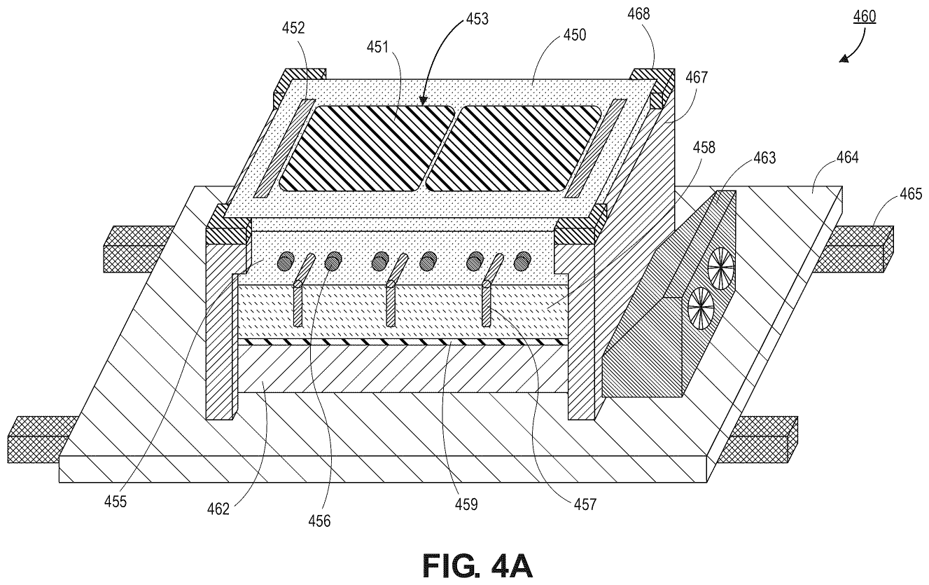

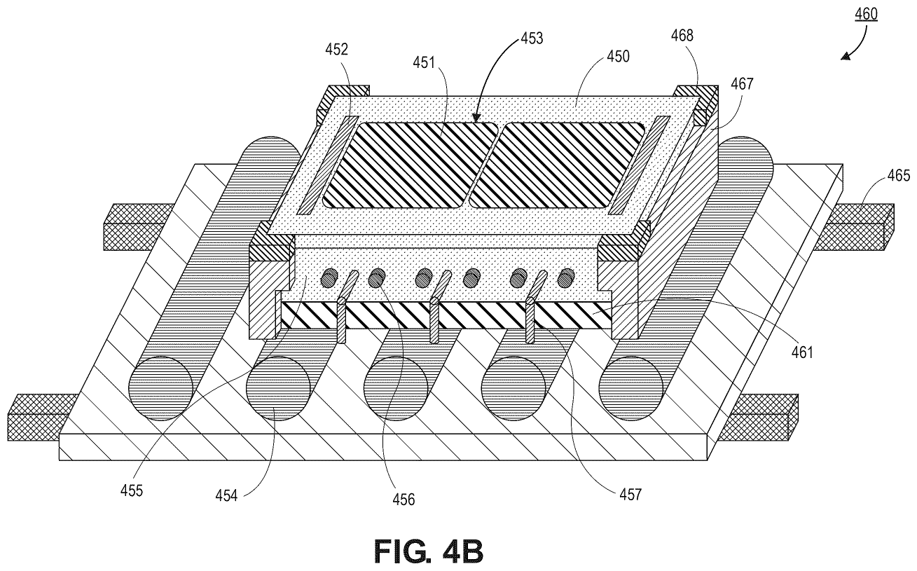

Referring now to FIGS. 5A and 5B, a series of cross-sectional illustrations that show the benefits of using a soft material chuck 550, such as graphite, is shown, in accordance with an embodiment. As shown, the substrate 551 has a backside 531 that faces away from the chuck 550 and a frontside 532 that faces the chuck 550. In an embodiment, the frontside 532 of the chuck 550 may have textured features 535. The textured features 535 may comprise any regular or irregular features that extend out from the frontside 532 of the substrate 551. For example, the textured features 535 may comprise pyramids or the like. While the pyramids are all shown as having uniform heights and widths, the features may have non-uniform dimensions.

In an embodiment, the chuck 550 may be similar to any of the chucks described in greater detail herein. For example, the chuck 550 may comprise graphite or the like. In an embodiment, the chuck 550 may comprise holes and channels for supplying a vacuum to secure the substrate 551 to the surface 537 of the chuck 550.

As shown in FIG. 5B, the substrate 551 is pressed down against the surface 537 of the chuck 550. Due to the softness of the chuck 550, the textured features 535 may press into the surface 537 of the chuck 550. For example, at least some of the textured features 535 may be at least partially embedded in the chuck 550. Since the textured features 535 at least partially embed into the chuck 550, the pressure is distributed across a larger surface area of the textured features 535 compared to previous solutions with a non-deformable surface. This results in a lower chance of damage to the textured features 535. As such, the efficiency of the solar cells formed on the substrate 551 may be improved since there is a significant reduction in damage to the textured features 535 of the frontside 532.

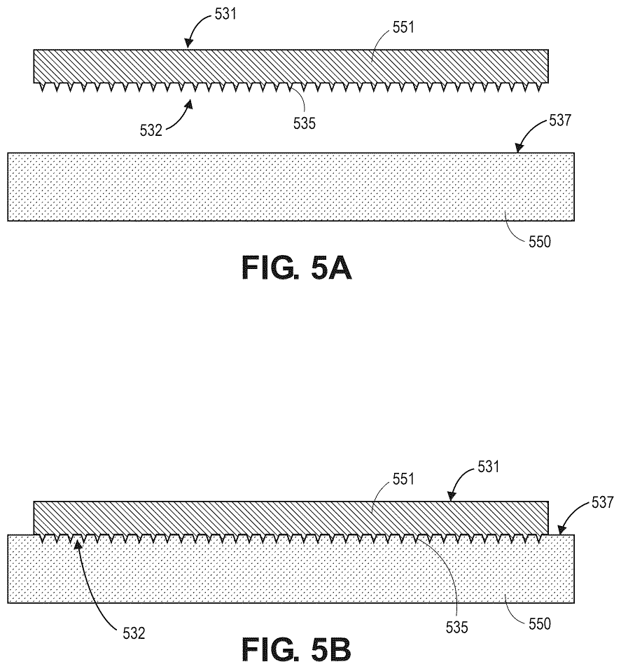

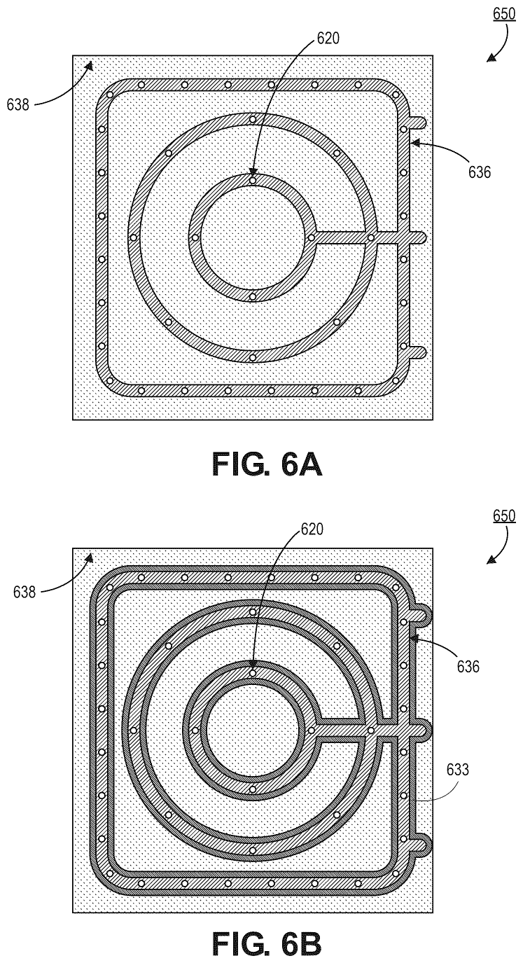

Referring now to FIGS. 6A and 6B, a pair of plan view illustrations of a backside surface 638 of a chuck 650 is shown, in accordance with an embodiment. As shown, a series of grooves or channels 636 may be formed into the backside surface 638. When the chuck 650 is pressed up against a hotplate (not shown), the channels 636 are sealed to provide a vacuum path. Holes 620 may be provided along the channels 636 so that the holes intersect the channels 636 and/or exit the chuck 650 at the channels 636. In some embodiments, the opposite end of the holes 620 may exit the chuck 650 along a recess in the chucking surface that is used to retain a substrate, a busbar, or the like. In an embodiment, the channels 636 have rectangular and/or circular shapes. Embodiments may include any number of channels 636 and/or any pattern for the channels 636.

In some embodiments, the soft material for the chuck 650 may allow for a vacuum tight seal to be made against the hotplate, and a gasket is not needed around the channels 636. However, in some embodiments a gasket 633 may be formed around the channels 636, as shown in FIG. 6B. When a gasket 633 is used, it may be appreciated that the gasket 633 may be a high temperature gasket 633 to be compatible with the thermocompression bonding process.

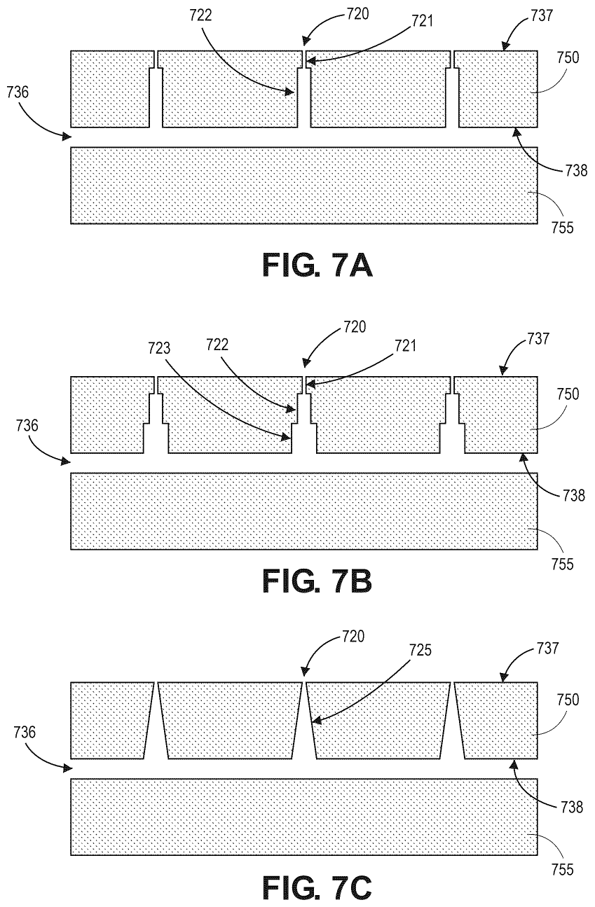

Referring now to FIGS. 7A-7C, a series of cross-sectional illustrations that depict the channels 736 and vacuum ports 720 in a chuck 750 that is over a hotplate 755 is shown, in accordance with an embodiment. As described above, the set of vacuum ports 720 and channels 736 allow for the chuck 750 to secure a substrate (not shown) to the top surface 737 when a vacuum is applied. That is, the atmospheric pressure over the substrate holds the substrate against the chuck 750. Since the substrate will span across the vacuum ports 720 in the chuck 750, the vacuum ports 720 cannot be too large. When the openings of the vacuum ports 720 at the top surface 737 are too large, the substrate may crack due to the substrate bending into the opening due to the atmospheric pressure that presses down on the substrate and/or the forces applied to the substrate during bonding.

However, small vacuum ports 720 constrict the air flow. Constricted air flow makes it more difficult to secure the substrate to the chuck with the vacuum. Accordingly, embodiments disclosed herein may comprise vacuum ports 720 that comprise openings with a first width at the top surface 737 and a second width at the bottom surface 738. The small width at the top surface 737 protects the substrate from damage, and the large width at the surface 738 maximizes the vacuum conductivity of the system.

In an embodiment, the vacuum ports 720 may have any suitable non-uniform width profile. In FIG. 7A, a single step is shown where the first width 721 transitions to the second width 722 with a single step. In FIG. 7B, a set of three widths 721, 722, and 723 with two steps is shown. In FIG. 7C, the vacuum ports 720 have a tapered sidewall 725 to provide a smooth change in the diameter of the vacuum ports 720.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a chuck, wherein a surface of the chuck comprises a material with a yield strength that is 100 MPa or less; and
a hotplate configured to be thermally coupled to the chuck.

2. The apparatus of claim 1, wherein the material comprises graphite.

3. The apparatus of claim 2, wherein the material comprises isostatically molded fine grain graphite.

4. The apparatus of claim 1, further comprising:
a recess into the surface of the chuck.

5. The apparatus of claim 1, further comprising:
a support plate below the hotplate, wherein the support plate comprises an insulating material.

6. The apparatus of claim 5, wherein the support plate comprises a ceramic and/or a composite material.

7. The apparatus of claim 5, further comprising:
a cooling channel between the support plate and the hotplate.

8. The apparatus of claim 7, further comprising:
a fan configured to blow air through the cooling channel.

9. The apparatus of claim 5 further comprising:
a plurality of rollers between the support plate and the hotplate.

10. The apparatus of claim 1, further comprising:
a groove in a second surface of the chuck that faces the hotplate.

11. The apparatus of claim 10, further comprising:
a hole through a thickness of the chuck, wherein the hole intersects the groove.

12. The apparatus of claim 11, wherein the hole comprises a non-uniform width through the thickness of the chuck.

13. An apparatus, comprising:
a chuck, wherein the chuck comprises a material with a yield strength that is 100 MPa or less;
a channel into a first surface of the chuck; and
a hole into a second surface of the chuck, wherein the hole passes through the chuck and exits within the channel, and wherein the hole has a non-uniform width.

14. The apparatus of claim 13, wherein the material comprises graphite.

15. The apparatus of claim 13, wherein the material comprises isostatically molded fine grain graphite.

16. The apparatus of claim 13, further comprising:
a recess into the second surface of the chuck.

17. The apparatus of claim 16, wherein the hole intersects the recess.

18. The apparatus of claim 13, further comprising:
a hotplate coupled to the first surface of the chuck, wherein the hotplate and the channel define a sealed fluidic path.

19. The apparatus of claim 18, wherein the hotplate directly contacts the first surface of the chuck.

20. The apparatus of claim 18, further comprising:
a high temperature gasket between the hotplate and the chuck.
